(19) United States
(12) Patent Application Publication
(10) Pub. No.: US 2011/0155246 A1
(43) Pub. Date: Jun. 30, 2011

(54) THIN FILM SOLAR CELL AND MANUFACTURING METHOD THEREOF

(76) Inventors: Chih-Hung YEH, Houli Township (TW); Wei-Lun LU, Houli Township (TW); Bing-Yi HOU, Houli Township (TW); Kuang-Chieh LAI, Houli Township (TW)

(21) Appl. No.: 12/648,752

(22) Filed: Dec. 29, 2009

(51) Int. Cl. H01L 31/0304; H01L 31/18

(52) U.S. Cl. 136/262; 136/252; 438/93

(57) ABSTRACT

The present invention relates to a thin film solar cell and manufacturing method thereof. The thin film solar cell comprises a substrate, a front electrode layer, an absorber layer and a rear electrode layer stacked in such sequence, wherein the front electrode layer is formed by doping group III element into a zinc oxide. The thin-film solar cell further comprise an interlayer disposed between the front electrode layer and the absorber layer wherein the interlayer has p-type holes formed by introducing nitrogen-based gas having Argon (Ar) as a carrier gas interacted with the group III element by using PECVD or thermal treatment, implementation and diffusion on the front electrode layer surface so that the concentration of nitrogen atoms in the interlayer is greater than 10¹⁵/cm³.

### FIELD OF THE INVENTION

The invention relates to a thin film solar cell and manufacturing method thereof, and more particularly to the thin film solar cell and manufacturing method thereof using nitrogen-based gas for TCO surface treatment.

### DESCRIPTION OF PRIOR ART

A conventional thin film solar cell comprises a substrate, a front electrode layer, an absorber layer and a back electrode layer. Particularly, the front electrode layer uses transparent conductive oxide (TCO) as its material. For the sake of obtaining better open-circuit voltage and preventing damage to the TCO surface from hydrogen plasma generated by plasma-enhanced chemical vapor deposition (PECVD) used for manufacturing the absorber layer. Conventionally, a thin film of p-type TCO is usually formed on the glass or n-type TCO as a protection layer so as to restrain the damage to the TCO surface. However, the process of producing the p-type TCO is too complicated so that mass production of thin film solar cell is limited.

Although U.S. Pat. No. 6,908,782 has disclosed a structure of p-type TCO, and U.S. Pat. No. 6,638,846 has also disclosed a method of growing a p-type TCO and manufacturing a light emitting device based on the p-type TCO. Nevertheless, the aforementioned prior arts have not disclosed the way to integrating the p-type TCO for manufacturing the thin film solar cell. Thus, a need exists for providing the thin film of p-type TCO in solar cell manufacture which has positive impacts on mass production and photoelectric conversion effect of thin film solar cells, and can use the existing conventional equipment and infrastructure.

### SUMMARY OF THE INVENTION

In light of the aforesaid problems, a thin film solar cell has been disclosed in the invention. The thin film solar cell comprises a substrate, a front electrode layer, an absorber layer and a rear electrode layer stacked in such sequence, where the front electrode layer is formed by doping group III element into a zinc oxide. The thin-film solar cell further comprise an interlayer disposed between the front electrode layer and the absorber layer wherein the interlayer has p-type holes formed by introducing nitrogen-based gas having Argon (Ar) as a carrier gas interacted with the group III element by using PECVD or thermal treatment, implementation and diffusion on the front electrode layer surface so that the concentration of nitrogen atoms in the interlayer is greater than 10¹⁵/cm³.

Therefore, it is a primary objective of the invention to propose a thin film solar cell that has the p-type interlayer having wok function of 5˜7 eV and disposed between the front electrode layer and the absorber layer, so as to enhance the open-circuit voltage of the thin film solar cell.

Besides, a manufacturing method of a thin film solar cell has been disclosed in the invention. The method comprises: providing a substrate; depositing a front electrode layer on a top of the substrate, where the front electrode layer is formed by means of doping group III element into a zinc oxide; depositing an interlayer on the front electrode layer, where the interlayer has a plurality of p-type holes that are formed by introducing a nitrogen-based gas containing Argon (Ar) as a carrier gas interacted with the group III element so that interlayer has the concentration of nitrogen atoms greater than 10¹⁵/cm³; depositing an absorber layer on the interlayer; and depositing a rear electrode layer on the absorber layer.

Therefore, it is a primary objective of the invention is to propose a method of manufacturing the thin film solar cell where the p-type interlayer is formed on the front electrode layer so as to restrain the damage to the TCO surface, and further to prevent damage to the TCO surface from hydrogen plasma generated by plasma-enhanced chemical vapor deposition (PECVD) used for manufacturing the absorber layer.

it is a another objective of the invention is to propose a method of manufacturing the thin film solar cell where the interlayer is formed on the absorber layer by doping group III element into a zinc oxide of the front electrode layer, and thus the process of producing the p-type TCO is simplified so as to improve the mass production of thin film solar cell.

### BRIEF DESCRIPTION OF DRAWINGS

The structure and the technical means adopted by the present invention to achieve the above and other objectives can be best understood by referring to the following detailed description of the preferred embodiments and the accompanying diagrams.

FIG. 1 is a schematic view that shows a thin film solar cell according to a first preferred embodiment of the invention.

FIG. 2 is a schematic flow that shows a manufacturing method of a thin film solar cell according to a second preferred embodiment of the invention.

### DETAILED DESCRIPTION OF PREFERRED EMBODIMENTS

A thin film solar cell and manufacturing method thereof has been disclosed in the invention; wherein the principles of photoelectric conversion employed in solar cell may be easily comprehended by those of ordinary skill in relevant technical fields, and thus will not be further described hereafter. Meanwhile, it should be noted that the drawings referred to in the following paragraphs only serve the purpose of illustrating structures related to the characteristics of the disclosure, and are not necessarily drawn according to actual scales and sizes of the disclosed objects.

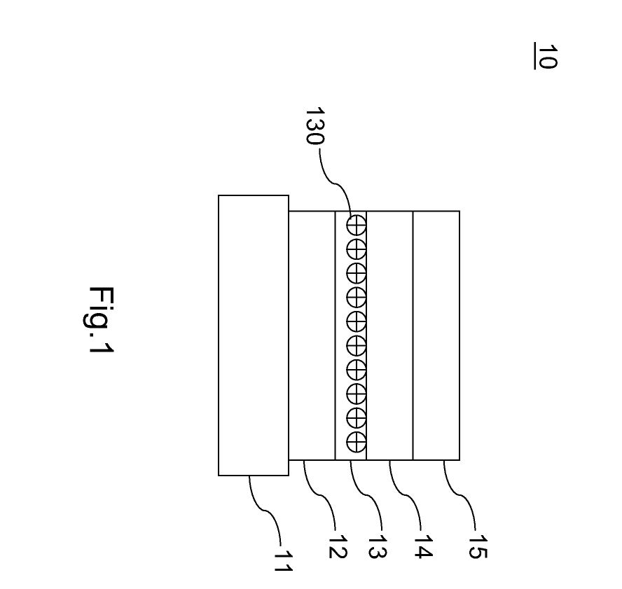

Refer to FIG. 1, which is a sectional view that show a thin film solar cell according to a first preferred embodiment of the invention. The thin film solar cell 10 comprises a substrate 11, a front electrode layer 12, an absorber layer 14 and a rear electrode layer 15 stacked in such sequence, wherein the front electrode layer 12 is formed by means of doping group III element into a zinc oxide. The thin-film solar cell 10 further comprise an interlayer 13 that is disposed between the front electrode layer 12 and the absorber layer 14. The interlayer 13 comprises a plurality of p-type holes 130 that are formed by means of introducing nitrogen-based gas having Argon (Ar) as a carrier gas interacted with the group III element so that the concentration of nitrogen atoms in the interlayer 13 is greater than 10¹⁵/cm³.

In the aforementioned preferred embodiment of the invention, the nitrogen-based gas can be NO, N2O, NO2, NH3 (ammonia), or N2. Besides, the interlayer 13 consists essentially of nitrogen, oxygen, hydrogen, and either binary or ternary compound of nitrogen and group III element. Besides, the compound of nitrogen and group III element can be aluminum nitride (Al—N) or gallium nitride (Ga—N). Besides, the interlayer 13 has a thickness of between 10 Å and 150 Å, or greater than 10 Å. Moreover, the thickness of the interlayer 13 in the best mode is 50 Å. Besides, the front electrode layer 12 is TCO, which is primarily formed of group III element oxide. On the other hand, the front electrode layer 12 can be AZO, GZO, BZO and IZO, and the group III element can be aluminum (Al), gallium (Ga), indium (In), or boron (B). Besides, the front electrode layer 12 has a thickness of greater than 1000 Å. Besides, the rear electrode layer 15 can be a single layer or double layer. If the rear electrode layer 15 is a single layer, then it is formed of metal. If the rear electrode layer 15 is a double layer, then it is formed of TCO and metal where the metal is Ag, Al, TiAg alloy, or TiAl alloy.

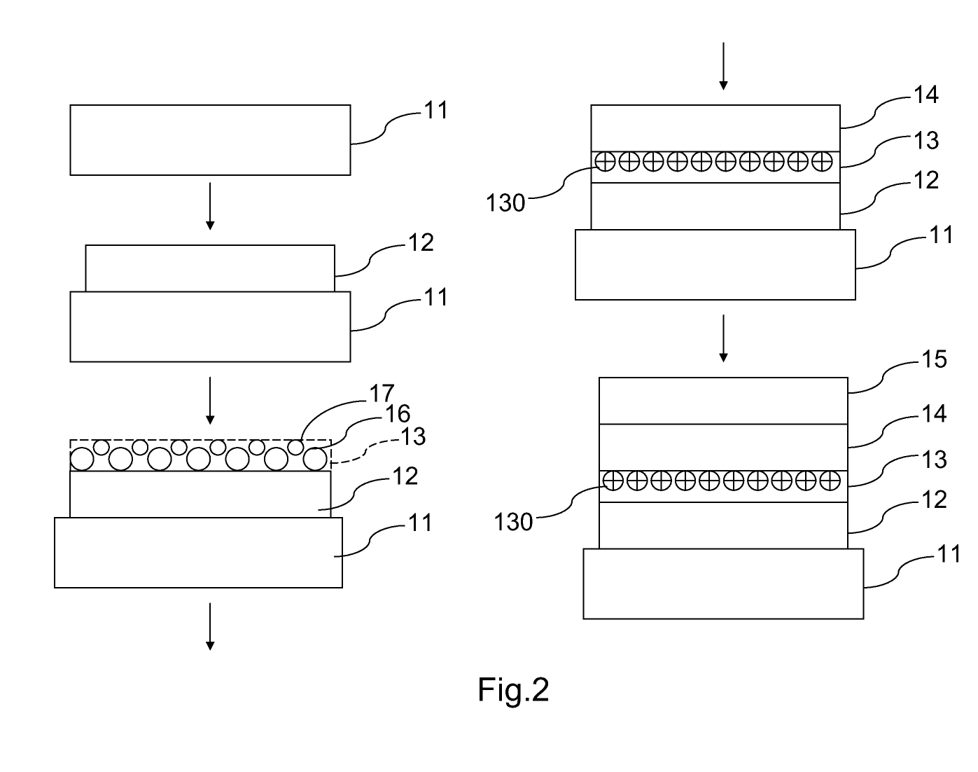

Refer to FIG. 2, which are schematic flows that show a manufacturing method of a thin film solar cell according to a second preferred embodiment of the invention. The method of manufacturing a thin film solar cell comprises the steps of:

(1) providing a substrate 11;
(2) depositing a front electrode layer 12 on a top of the substrate 11, where the front electrode layer 12 is formed by means of doping group III element into a zinc oxide;
(3) depositing an interlayer 13 on the front electrode layer 12, where the interlayer 13 (indicated by dot-line) has a plurality of p-type holes 130 that are formed by introducing a nitrogen-based gas 16 containing Argon (Ar) as a carrier gas 17 interacted with the group III element by using PECVD or thermal treatment, implementation and diffusion on the front electrode layer surface so that interlayer 13 has a plurality of p-type holes 130 and the concentration of nitrogen atoms is greater than 10¹⁵/cm³;
(4) depositing an absorber layer 14 on the interlayer 13; and
(5) depositing a rear electrode layer 15 on the absorber layer 14.

In the aforementioned preferred embodiment of the invention, the front electrode layer 12 can be formed on the substrate 11 by a sputtering process, normal pressure chemical vapor deposition (NPCVD) or low pressure chemical vapor deposition (LPCVD). Besides, the absorber layer 14 can be formed by a process so called plasma enhanced chemical vapor deposition (PECVD). Besides, the rear electrode layer 15 is formed on the absorber layer 14 by either a sputtering process or physical vapor deposition (PVD). Besides, features of the substrate 11, the front electrode layer 12, the interlayer 13, the absorber layer 14, and the rear electrode layer 14 mentioned above are as described in the aforesaid first preferred embodiment.

Although a preferred embodiment of the invention has been described for purposes of illustration, it is understood that various changes and modifications to the described embodiment can be carried out without departing from the scope and the spirit of the invention as disclosed in the appended claims.

What is claimed is:

1. A thin film solar cell, comprising a substrate, a front electrode layer, a photoelectric conversion layer and a rear electrode layer stacked in such sequence, wherein said front electrode layer is formed by doping group III element into a zinc oxide, characterized in that:
said thin-film solar cell further comprise an interlayer disposed between said front electrode layer and said absorber layer, wherein said interlayer has p-type holes formed by introducing a nitrogen-based gas containing Argon (Ar) as a carrier gas interacted with said group III element so that the concentration of nitrogen atoms in said interlayer is greater than 10¹⁵/cm³.

2. The thin film solar cell of claim 1, wherein said nitrogen-based gas is selected from the group consisting of NO, N2O, NO2, NH3, and N2.

3. The thin film solar cell of claim 1, wherein said interlayer consists essentially of nitrogen, oxygen, hydrogen, and compound of nitrogen and group III element.

4. The thin film solar cell of claim 1, wherein said interlayer consists essentially of nitrogen, oxygen, hydrogen, and binary compound of group III elements and nitrogen.

5. The thin film solar cell of claim 1, wherein said interlayer consists essentially of nitrogen, oxygen, hydrogen, and ternary compound of group III elements and nitrogen.

6. The thin film solar cell of claim 1, wherein said compound of nitrogen and group III element is aluminum nitride (Al—N) or gallium nitride (Ga—N).

7. The thin film solar cell of claim 1, wherein said interlayer has a thickness of between 10 Å and 150 Å.

8. The thin film solar cell of claim 1, wherein said interlayer has a thickness of greater than 10 Å.

9. The thin film solar cell of claim 1, wherein said group III element is selected from the group consisting of aluminum (Al), gallium (Ga), indium (In), and boron (B).

10. The thin film solar cell of claim 1, wherein said front electrode layer is selected from the group consisting of AZO, GZO, BZO, and IZO.

11. The thin film solar cell of claim 1, wherein said front electrode layer has a thickness of greater than 1000 Å.

12. The thin film solar cell of claim 1, wherein said front electrode layer is group III oxide.

13. The thin film solar cell of claim 1, wherein said rear electrode layer is a single layer formed of metal.

14. The thin film solar cell of claim 1, wherein said rear electrode layer is a double layer formed of transparent conductive oxide (TCO) and metal.

15. The thin film solar cell of claim 1, wherein said metal is selected from the group consisting of Ag, Al, TiAg alloy, and TiAl alloy.

16. A method of manufacturing a thin film solar cell, comprising the steps of:
providing a substrate;
depositing a front electrode layer on a top of said substrate, wherein said front electrode layer is formed by doping group III element into a zinc oxide;
depositing an interlayer on said front electrode layer, wherein said interlayer is formed by introducing a nitrogen-based gas containing Argon (Ar) as a carrier gas interacted with said group III element by using PECVD or thermal treatment, implementation and diffusion on said front electrode layer surface so that the concentration of nitrogen atoms in said interlayer is greater than 10¹⁵/cm³;
depositing an absorber layer on said interlayer; and
depositing a rear electrode layer on said absorber layer.

17. The method of manufacturing a thin film solar cell of claim 16, wherein said front electrode layer is formed on said substrate by a process selected from a group consisting of sputtering process, normal pressure chemical vapor deposition (NPCVD) and low pressure chemical vapor deposition (LPCVD).

18. The method of manufacturing a thin film solar cell of claim 16, wherein said absorber layer is formed by plasma enhanced chemical vapor deposition (PECVD).

19. The method of manufacturing a thin film solar cell of claim 16, wherein said rear electrode layer is formed on said absorber layer by a process selected from a group consisting of sputtering process and physical vapor deposition (PVD).
